(19) United States
(12) Patent Application Publication
(10) Pub. No.: US 2010/0117741 A1
(43) Pub. Date: May 13, 2010

(54) PLL Circuit

(75) Inventor: Shigetaka Goto, Aichi (JP)

Correspondence Address: WOODCOCK WASHBURN LLP, CIRA CENTRE, 12TH FLOOR, 2929 ARCH STREET, PHILADELPHIA, PA, 19104-2891, US

(73) Assignee: KABUSHIKI KAISHA TOYOTA JIDOSHOKKI, Aichi (JP)

(21) Appl. No.: 12/608,811

(22) Filed: Oct. 29, 2009

(30) Foreign Application Priority Data
Nov. 12, 2008 (JP) 2008-289372

(51) Int. Cl. H03L 7/00

(52) U.S. Cl. 331/17

(57) ABSTRACT

A VCO/current switching circuit outputs a VCO selection signal for selecting one VCO out of two or more VCOs on the basis of the externally provided frequency division data. Moreover, when switching the VCOs, the VCO/current switching circuit outputs a switching signal for changing the output current of the variable charge pump to a larger value than normal (value when it is locked). After completing the switching of the VCOs, the VCO/current switching circuit outputs a switching signal for changing the output current of the variable charge pump to a normal small value.

### CROSS REFERENCE TO RELATED APPLICATION

This application claims priority to Japanese Application No. 2008-289372 filed Nov. 12, 2008.

### TECHNICAL FIELD

The present invention relates to a PLL performing an oscillation operation by selecting one VCO out of two or more VCOs whose oscillation frequency bands are different from each other.

### BACKGROUND

In tuners for receiving signals of a wide frequency range (for example, TVs), two or more voltage controlled oscillators (VCOs) whose oscillation frequency bands are different from each other are switched in order to cover the frequency range.

Patent Document 1 discloses a PLL having a charge pump circuit and a resistor, and having a frequency divider for dividing a capacitor and an oscillation signal at a predetermined frequency division ratio, including switching means for switching at least two circuit constants of the current value of an output signal from the charge pump circuit, the value of resistance, the capacitance value of a capacitor, and the frequency division ratio of the frequency divider, where the switching means modify the frequency band of the PLL with a damping factor of the PLL being constant when switching the circuit constants. Due to this configuration, a favorable phase pulling effect with sufficient convergence speed can be achieved while also maintaining the stability of the loop.

Patent Document 2 discloses the features of counting the phase difference between an UP signal and a DOWN signal that are output from a phase comparator, and converting a digital count value into an analog signal by using a D/A converter. Accordingly, the control of a charge pump becomes easy.

Patent Document 3 discloses a two-mode PLL that switches a resistance value of the low-pass filter by using a switch, where the loop characteristics when it is pulled-in and when it is locked are changed by switching the drive current of a charge pump depending on the mode. Accordingly, a PLL that is applicable for an IC and is relatively free from disturbance can be provided.

However, there is a problem in which, when switching two or more VCOs having varying oscillation frequency bands, it takes a long time until a PLL is locked if a VCO is switched so as to match the frequency of a target in the linear search.

Patent Document 1: Japanese Laid-open Patent Publication No. 2006-222939

Patent Document 2: Japanese Laid-open Patent Publication No. H08-288843

Patent Document 3: Japanese Laid-open Patent Publication No. S62-92521

### SUMMARY

An object of the present invention is to reduce the time in which a PLL is locked.

A PLL according to the present invention includes a plurality of VCOs whose oscillation frequency bands are different from each other, a programmable frequency divider, a charge pump, and a VCO/current switching circuit configured to select one of the plurality of VCOs on the basis of frequency division data determining a frequency division ratio of the programmable frequency divider, and to switch a current value of the charge pump to a larger value than normal when switching the VCOs.

According to the present invention, the VCOs can be switched to VCOs whose frequency bands are optimal on the basis of the frequency division data. Moreover, when switching the VCOs, the time in which the PLL is locked can be reduced by increasing the current value of the charge pump.

In the above PLL, the VCO/current switching circuit further comprises a first determination circuit configured to output a selection signal for selecting one VCO out of the plurality of VCOs on the basis of frequency division data determining a frequency division ratio of the programmable frequency divider; a second determination circuit configured to compare a control voltage for controlling an oscillation frequency of a VCO with a first reference value and a second reference value, to select a currently selected VCO when the control voltage is determined to be equal to or higher than the first reference value and equal to or lower than the second reference value, to output a signal for selecting a VCO whose oscillation frequency band is the next largest from the currently selected VCO when the control voltage is determined to be larger than the second reference value, and to output a signal for selecting a VCO whose oscillation frequency band is the next lowest from the currently selected VCO when the control voltage is determined to be lower than the first reference value; and a selector configured to select an output out of the first determination circuit and the second determination circuit, and to output the selected output as a VCO selection signal.

Due to the above configuration, even if the control voltage that controls the oscillation frequency of the VCO fluctuates, it can be switched to a VCO whose oscillation frequency band is preferable.

In the above PLL, when switching a reception channel, the selector firstly selects the first determination circuit, and from then on, selects the second determination circuit.

In the above PLL, when the frequency division data is modified, the selector firstly selects an output of the first determination circuit and outputs a switching signal for changing a current value of the charge pump to a larger value than normal, and from then on, when a signal for switching the VCOs is not output from the second determination circuit, the selector outputs a switching signal to change a current value of the charge pump to a normal small value.

Due to the above configuration, a selection signal of the VCOs output from the first determination circuit and a switching signal for changing the current value of the charge pump to a larger value than normal are firstly output when the frequency division data is modified to switch a reception channel, and from then on, when a VCO selection signal for switching the VCOs is not output from the second determination circuit, a switching signal for changing the current value of the charge pump to a normal small value is output. Accordingly, the time during which the PLL is locked can be reduced by changing the current value of the charge pump to a larger value when switching the VCOs.

### BRIEF DESCRIPTION OF THE DRAWINGS

FIG. 1 is a circuit diagram illustrating a PLL according to an embodiment of the present invention.

FIG. 2 is a diagram illustrating an exemplary variable charge pump.

FIG. 3 is a diagram illustrating a configuration of a VCO/current switching circuit.

FIG. 4A is a diagram illustrating the relationship between oscillation frequency and frequency division data of VCOs and a frequency control voltage, and FIG. 4B is a diagram illustrating the correspondence relationship between the frequency division data and the VCOs.

FIG. 5 is a flow chart illustrating the operation of a PLL.

### DETAILED DESCRIPTION OF ILLUSTRATIVE EMBODIMENTS

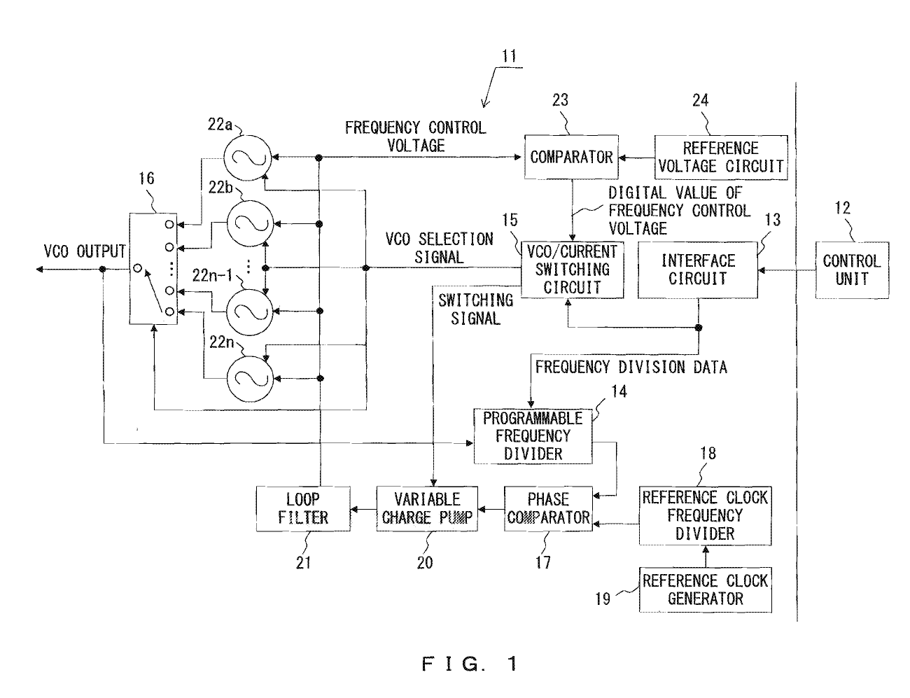

Some embodiments of the present invention will be described. FIG. 1 is a block diagram illustrating a PLL configuration according to an embodiment.

A PLL 11 is incorporated, for example, in an IC for a TV tuner, and is a circuit for selecting, out of two or more VCOs, a VCO of a frequency band suitable for the frequency of a broadcasting station to be received.

In FIG. 1, a control unit (processor) 12 outside the IC for a TV tuner outputs the frequency division data (data designating the frequency division ratio of programmable frequency divider 14) corresponding to the frequency of a broadcasting station that the user wishes to receive to an interface circuit 13 of the IC for the TV tuner.

The interface circuit 13 outputs the frequency division data received from the control unit 12 to a programmable frequency divider 14 and a VCO/current switching circuit 15.

The VCO/current switching circuit 15 outputs a VCO selection signal for selecting one of two or more VCOs 22a-22n on the basis of the frequency division data, and a switching signal for changing the output current of a variable charge pump 20 to a value larger than a normal value (value when it is locked).

The programmable frequency divider 14 divides the oscillation signal output from the VCO output circuit 16 by the frequency division ratio designated by the frequency division data, and thereby outputs the divided oscillation signal to a phase comparator 17.

The frequency division ratio of the programmable frequency divider 14 can be determined by the oscillation frequency of the VCO and the comparison frequency (frequency of clock signal) of the PLL. In the embodiment of the present invention, as the frequency of a clock signal to be input into the phase comparator 17 is constant, a VCO having an oscillation frequency band suitable for the frequency of the broadcasting station can be preliminary determined on the basis of the frequency of a clock signal and the frequency division data. Accordingly, the VCO/current switching circuit 15 can generate a signal for selecting a VCO of a suitable oscillation frequency band on the basis of the frequency division data.

Upon providing another frequency divider before the programmable frequency divider 14, the oscillation signal output from the VCO output circuit 16 may be divided by that frequency divider, and subsequently may be further divided by the programmable frequency divider 14. By using frequency dividers at two or more stages, the frequency division ratio of the programmable frequency divider 14 does not have to be set very high even if the oscillation frequency is high.

A reference clock generator 19 is a circuit for generating a reference clock signal by using a quartz oscillator or the like. A reference clock frequency divider 18 divides the reference clock signal output from the reference clock generator 19 by a predetermined frequency division ratio, and outputs a clock signal of a specific frequency to the phase comparator 17.

The phase comparator 17 compares the phase of the output signal of the programmable frequency divider 14 and the phase of the clock signal output from the reference clock frequency divider 18, and outputs a signal in accordance with the phase difference to the variable charge pump 20.

The variable charge pump 20 turns on a transistor on a power supply side or on a ground side (or negative potential side) to recharge or discharge the capacitor of a loop filter 21 in accordance with an UP signal or a DOWN signal output from the phase comparator 17. Moreover, the variable charge pump 20 modifies a current value to be supplied to a loop filter 21 on the basis of a switching signal output from the VCO/current switching circuit 15.

The loop filter 21 flattens the output current of the variable charge pump 20, and outputs the flattened output current as a frequency control voltage for controlling the oscillation frequency of VCOs 22a-22n.

The VCOs 22a-22n are voltage controlled oscillators whose oscillation frequency bands are different from each other, and one of the oscillation signals of these VCOs 22a-22n is selected by the VCO output circuit 16, thereby outputting the selected oscillation signal to the programmable frequency divider 14 and other circuits (not illustrated).

The PLL is comprised of the programmable frequency divider 14, the phase comparator 17, the variable charge pump 20, the loop filter 21, the VCOs 22a-22n, or the like, which are described in the above.

The comparator 23 compares the analog frequency control voltage output from the loop filter 21 with the analog reference voltage output from a reference voltage circuit 24, and thereby converts the analog frequency control voltage into a digital value.

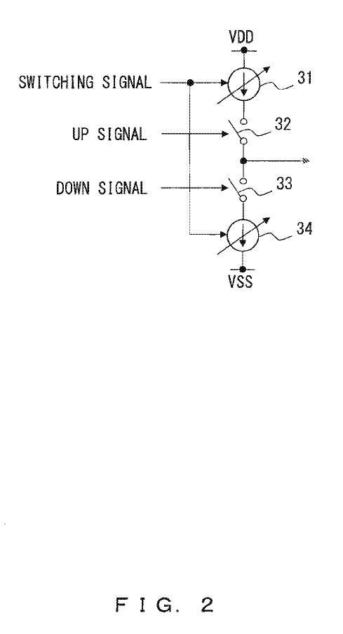

FIG. 2 is a diagram illustrating an exemplary variable charge pump 20. The variable charge pump 20 is provided with a variable current source 31 connected to a positive power supply VDD, switches 32 and 33 configured by a MOS transistor or the like, and a variable current source 34 connected to a negative power supply VSS or the ground.

To the variable current sources 31 and 34, a switching signal of electric current is provided from the VCO/current switching circuit 15. When a switching signal for changing a current value to a larger value than normal is provided from the VCO/current switching circuit 15, the output current of the variable current sources 31 and 34 increases. When a switching signal for changing a current value to a smaller value is provided from the VCO/current switching circuit 15, the output current of the variable current sources 31 and 34 decreases. In other words, the variable charge pump 20 outputs a larger electric current than normal when switching a VCO, and outputs a small electric current at other times.

To switches 32 and 33, an UP signal or a DOWN signal is respectively given from the phase comparator 17. When an UP signal is given, the switch 32 becomes turned on and the switch 33 is turned off, and thereby the output current of the variable current source 31 is provided to a capacitor of the loop filter 21. On the other hand, when a DOWN signal is given, the switch 32 becomes turned off and the switch 33 becomes turned on, and thereby the electric charge accumulated in a capacitor of the loop filter 21 is discharged via the variable current source 34.

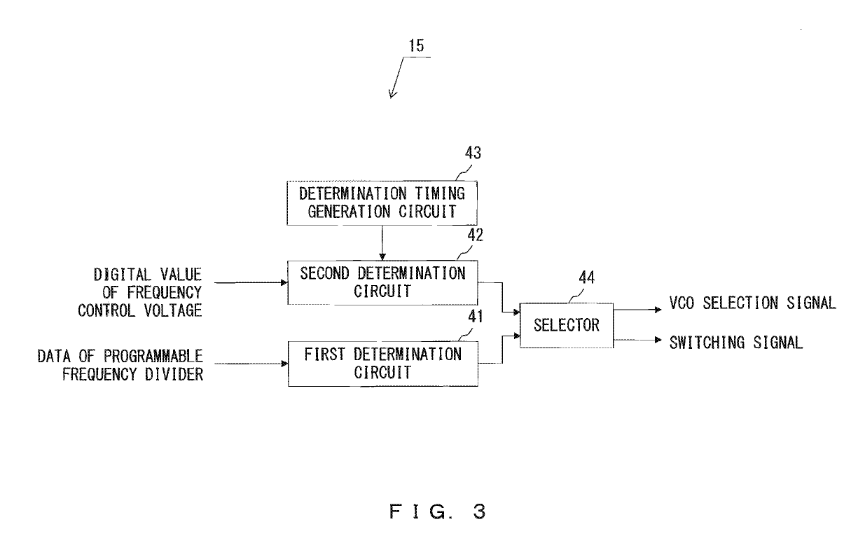

FIG. 3 is a diagram illustrating one exemplary configuration of the VCO/current switching circuit 15. The VCO/current switching circuit 15 is comprised of a first determination circuit 41, a second determination circuit 42, a determination timing generation circuit 43, and a selector 44.

The first determination circuit 41 outputs a VCO selection signal for selecting one VCO out of two or more VCOs on the basis of the frequency division data given externally from the control unit 12.

The second determination circuit 42 performs the following determination operations with the signal output from the determination timing generation circuit 43 being a trigger.

The second determination circuit 42 maintains the currently selected VCO when the digital value of the frequency control voltage output from the comparator 23 (FIG. 1) is determined to be equal to or larger than reference value B (corresponding to a first reference value) and to be equal to or smaller than reference value A (corresponding to a second reference value). Moreover, the second determination circuit 42 outputs a VCO selection signal for selecting a VCO whose oscillation frequency band is the next highest from the currently selected VCO when the digital value of the frequency control voltage is determined to be larger than reference value A. Furthermore, the second determination circuit 42 outputs a VCO selection signal for selecting a VCO whose oscillation frequency band is the next lowest from the currently selected VCO when the digital value of the frequency control voltage is determined to be smaller than reference value B. The reference value A and reference value B are set on the basis of the upper limit and the lower limit of the frequency control voltage in which the oscillation of a VCO can be stably performed under certain conditions, such as in a certain environmental temperature range.

The selector 44 firstly selects a VCO selection signal that is output from the first determination circuit 41, and then outputs a switching signal for changing the current value of the variable charge pump 20 to a larger value than normal when the frequency division data is modified and a switching of the VCOs is required. From then on, the selector 44 selects a VCO selection signal output from the second determination circuit 42. The selector outputs a switching signal for changing a current value of the variable charge pump 20 to a normal small value when a signal for switching the VCOs is not output from the second determination circuit 42.

Due to the VCO selection signal output from the selector 44, one VCO out of the two or more VCOs 22a-22n is selected, and an oscillation operation is performed. The VCO selection signal is also given to the VCO output circuit 16 as a selection signal, and the VCO output circuit 16 selects the output of a VCO designated by the VCO selection signal and thereby outputs the selected output to the programmable frequency divider 14.

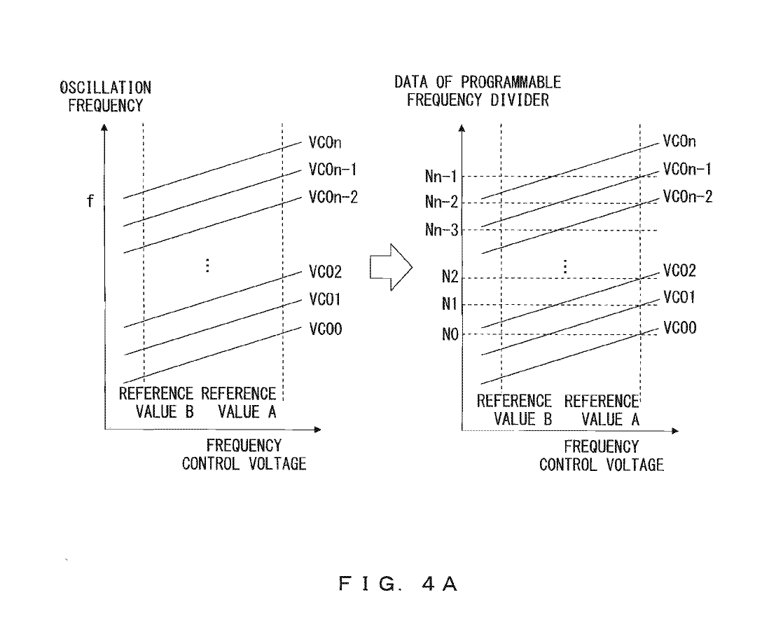

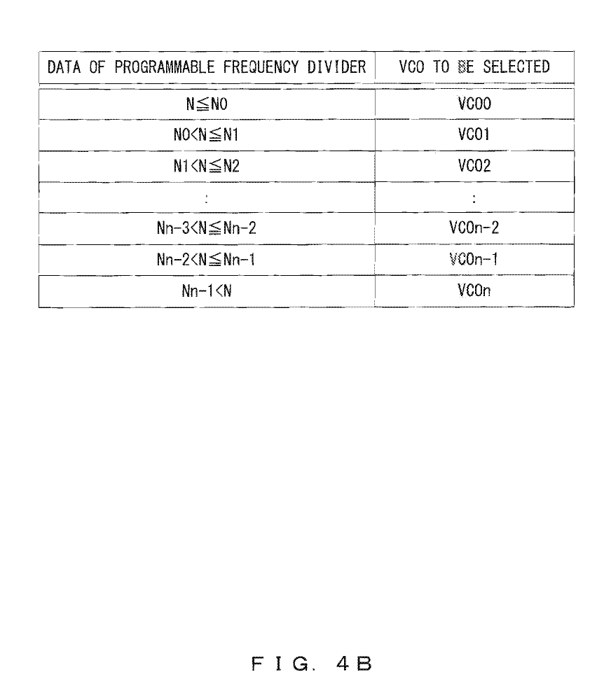

FIG. 4A is a diagram illustrating the relationship between oscillation frequency and frequency division data of the VCOs and a frequency control voltage, and FIG. 4B is a diagram illustrating the correspondence relationship between the frequency division data and the VCOs.

The diagram on the left of FIG. 4A illustrates the relationship between oscillation frequency of the VCOs and a frequency control voltage, and the diagram on the right of FIG. 4A illustrates the relationship between values of the frequency division data N0 through Nn−1 and a frequency control voltage.

Defining frequency division data as N, and defining comparison frequency (frequency of clock signal) of a PLL as fref, oscillation frequency fvco is represented by the following equation.

fvco=fref*N

Assuming that comparison frequency fref of a PLL is constant, frequency division data N can be determined by using the above equation if the frequency of the broadcasting station to be received is determined Accordingly, the frequency division data N and the VCO having a certain oscillation frequency band can be associated with each other.

In FIG. 4A, the VCO whose oscillation frequency band is the lowest is VCO0 (corresponding to VCO 22a of FIG. 1), the VCO whose oscillation frequency band is the second lowest is VCO1 (corresponding to VCO 22b of FIG. 1), . . . , the VCO whose oscillation frequency band is the second highest is VCOₙ₋₁ (corresponding to VCO 22ₙ₋₁ of FIG. 1), and the VCO whose oscillation frequency band is the highest is VCOn (corresponding to VCO 22n of FIG. 1).

For example, the value of frequency division data N is N0 when the frequency control voltage of VCO0 whose oscillation frequency band is the lowest is almost equal to reference value A that is the upper limit, the value of frequency division data N is N1 when the frequency control voltage of VCO1 whose oscillation frequency band is the second lowest is almost equal to reference value A, . . . , and the value of frequency division data N is Nₙ₋₁ when the frequency control voltage of VCOₙ₋₁ whose oscillation frequency band is the second highest is almost equal to reference value A.

In the present embodiment, the correspondence relationship between the frequency range division data N and the thereby selected VCO as illustrated in FIG. 4B is determined by using the above-described values of frequency division data N, i.e., N0 through Nₙ₋₁. In the example depicted in FIG. 4A, the frequency range division data N is determined by taking into account the overlapping frequency range or the like as the oscillation frequency bands of the VCOs partly overlap one another.

The operation of the VCO/current switching circuit 15 in FIG. 3 will now be described with reference to FIG. 4A and FIG. 4B.

When the frequency division data N set to the programmable frequency divider 14 fulfills the condition of N≦N0 (condition depicted in FIG. 4B; same for the following conditions), the first determination circuit 41 outputs a VCO selection signal for selecting VCO0, whose oscillation frequency band is the lowest (see FIG. 4A; same for the following VCOs).

When the frequency division data N fulfills the condition of N0<N≦N1, the first determination circuit 41 outputs a VCO selection signal for selecting VCO1, whose oscillation frequency band is the second lowest. When the frequency division data N fulfills the condition of N1<N≦N2, the first determination circuit 41 outputs a VCO selection signal for selecting VCO2, whose oscillation frequency band is the third lowest.

When the frequency division data N fulfills the condition of Nn−2<N≦Nn−1, the first determination circuit 41 outputs a VCO selection signal for selecting VCOₙ₋₁, whose oscillation frequency band is the second highest. Furthermore, when the frequency division data N fulfills the condition of Nn−1<N, the first determination circuit 41 outputs a VCO selection signal for selecting VCOn, whose oscillation frequency band is the highest.

Next, the operation of the second determination circuit 42 is described. The second determination circuit 42 compares the digital value of frequency control voltage with reference values A and B. For example, when it is determined that the digital value of a frequency control voltage is equal to or greater than reference value B, which is the lower limit, and is equal to or less than reference value A, which is the upper limit, while VCO1 is selected, the second determination circuit 42 maintains the VCO1 that is selected at that time.

When the digital value of frequency control voltage is determined to be larger than reference value A, the second determination circuit 42 outputs a VCO selection signal for selecting VCO2, whose oscillation frequency band is the next largest from the currently selected VCO1.

When the digital value of a frequency control voltage is determined to be smaller than reference value B, the second determination circuit 42 outputs a VCO selection signal for selecting a VCO0 whose oscillation frequency band is the next smallest from the currently selected VCO1.

In the present embodiment, for example, a value of N0<N≦N1 is set as data designating VCO1, whose oscillation frequency band is low, and when the digital value of the frequency control voltage is equal to or larger than reference value B and is equal to or smaller than reference value A, the second determination circuit 42 maintains “the value of the currently selected VCO”. Moreover, when the digital value of the frequency control voltage is determined to be larger than reference value A, the second determination circuit 42 outputs “the value of the currently selected VCO+1” as a VCO selection signal. When the digital value of the frequency control voltage is determined to be smaller than reference value B, the second determination circuit 42 outputs “the value of the currently selected VCO−1” as a VCO selection signal. The second determination circuit 42 may be configured, for example, by a decoder, a comparator, or the like.

When “the value of the currently selected VCO+1” is output as a VCO selection signal, the currently selected VCO terminates the oscillation operation, and the VCO whose oscillation band is second higher starts the oscillation operation. A circuit that switches the VCOs may be implemented, for example, by a switching circuit or the like. In FIG. 1, the VCO selecting signal input into the VCOs 22a-22n exemplarily indicates a function of the switching circuit that is controlled by the VCO selection signal.

When instructed by the control unit 12 or when the frequency division data is modified, the selector 44 firstly selects the VCO selection signal output from the first determination circuit 41, and outputs the selected VCO selection signal to the VCOs 22a-22n and the VCO output circuit 16 so as to operate a specific VCO. From then on, the selector 44 outputs the VCO selection signal (for example, a value in which “1” is added to the value of the currently selected VCO, or a value in which “1” is subtracted from the value of the currently selected VCO) output from the second determination circuit 42. Moreover, the selector 44 outputs a switching signal for increasing the current value of the variable charge pump 20 when switching the VCOs.

Accordingly, a signal is output for selecting the VCO whose oscillation frequency band corresponds to the frequency division data, and a switching signal is also output for switching the current value of the variable charge pump 20 to a larger value than the value when it is locked. Furthermore, when the frequency control voltage is smaller than reference value B or larger than reference value A, a signal for selecting the VCO whose oscillation frequency band is the next highest or the next lowest is output.

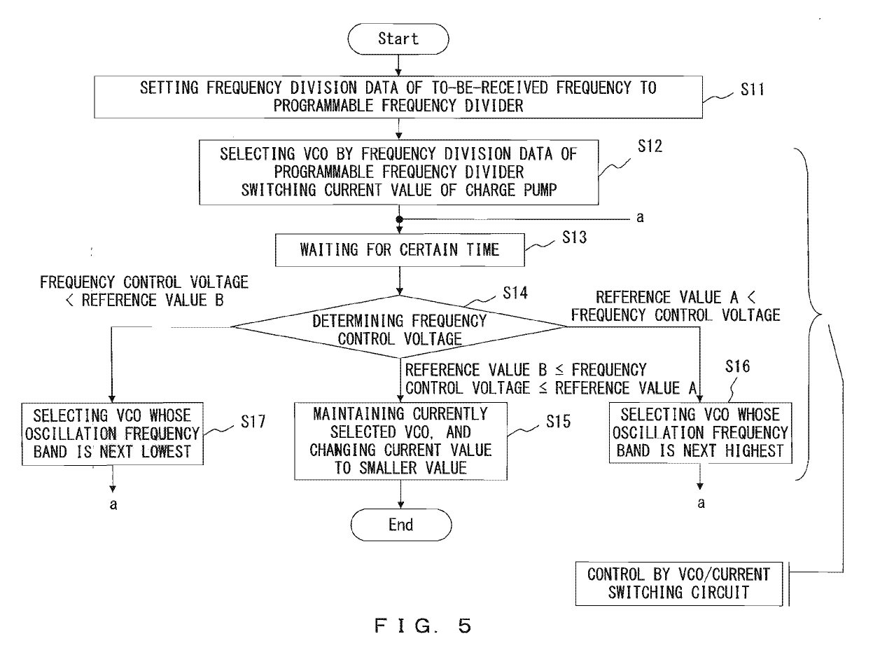

The operation of the PLL 11 will now be described with reference to the flow chart in FIG. 5.

Firstly, the frequency division data that corresponds to the frequency to be received is set to the programmable frequency divider 14 (S11 in FIG. 5).

Next, the VCO/current switching circuit 15 outputs a VCO selection signal for selecting the VCO that corresponds to the frequency division data to be set to the programmable frequency divider 14, and also outputs a switching signal for switching the current value of the variable charge pump 20 (S12).

Once a switching signal for changing the current value to a larger value is output from the VCO/current switching circuit 15, the current values of the variable current sources 31 and 34 of the variable charge pump 20 are changed to a larger value than the value when it is locked, and the frequency of the PLL is controlled with that larger current value. Accordingly, the oscillation frequency of the PLL 11 can be converged in a short time.

In the following step S13, the PLL 11 waits until the frequency control voltage becomes stable. After a certain length of time, the PLL 11 determines whether the digital value of the frequency control voltage is equal to or larger than reference value B and equal to or smaller than reference value A, whether the digital value of the frequency control voltage is larger than reference value A, or whether the digital value of the frequency control voltage is smaller than reference value B (S14).

When the digital value of the frequency control voltage satisfies the condition of “reference value B≦digital value of frequency control voltage≦reference value A”, the process proceeds to step S15, and the PLL 11 maintains the currently selected VCO, and outputs a switching signal for changing the current value of the variable charge pump 20 to a smaller value.

In step S14, when the digital value of the frequency control voltage is larger than the reference value, the process proceeds to step S16, and the PLL 11 outputs a VCO selection signal for selecting the VCO whose oscillation frequency band is the next largest from the oscillation frequency band of the currently selected VCO. At the same time, a switching signal for instructing the variable charge pump 20 to output a larger electric current than normal is output from the VCO/current switching circuit 15. Subsequently, the process proceeds back to step S13.

In step S14, when the digital value of the frequency control voltage is determined to be smaller than reference value B, the process proceeds to step S17, and the PLL 11 outputs a VCO selection signal for selecting the VCO with an oscillation frequency band is that is the next smallest from the oscillation frequency band of the currently selected VCO. At the same time, a switching signal for instructing the variable charge pump 20 to output a larger electric current than normal is output from the VCO/current switching circuit 15. Subsequently, the process proceeds back to step S13.

The processing in steps S12-S17 in the above represents the operations of the VCO/current switching circuit 15.

According to the above-described embodiment, on the basis of the frequency division data corresponding to a broadcasting station that is desired to be received, a VCO whose oscillation frequency band is preferable can be selected out of two or more VCOs. Moreover, when switching the VCOs, the PLL can be converged by increasing the current value of the variable charge pump 20.

Moreover, according to the above-described embodiment, the currently selected VCO is maintained when the digital value of the frequency control voltage for controlling the oscillation frequency of the VCO is within a certain range, and a VCO selection signal is output for selecting the VCO whose oscillation frequency band is the next largest when the digital value is larger than reference value A, which is the upper limit. Furthermore, when the digital value of the frequency control voltage is smaller than reference value B, which is the lower limit, a VCO selecting signal is output for selecting the VCO whose oscillation frequency band is the next smallest.

Due to the above configuration, a VCO whose oscillation frequency is close to the frequency of a broadcasting station that is desired to be received can be selected, and thus the time for the PLL being locked can be reduced.

Moreover, when there are fluctuations in the frequency control voltage due to changes in environmental temperature or other conditions, a VCO whose oscillation frequency band is suitable for the after-fluctuations conditions can be selected.

According to the above-described embodiment, a VCO whose frequency band is optimal can be selected out of two or more VCOs, and when the VCO is further switched, the time for the PLL being locked can be reduced.

The present invention is not limited to the above-described embodiment, but may be configured, for example, as follows.

(1) In the embodiment, the selector 44 selects one of the outputs between the first determination circuit 41 and the second determination circuit 42. However, the first determination circuit and the second determination circuit may be configured as one circuit, and they may be configured such that the one circuit generates a VCO selection signal on the basis of the frequency division data and compares reference value A with reference value B.

The first determination circuit 41, the second determination circuit 42, and the selector 44 may be integrated into one circuit.

(2) The embodiment is configured such that the second determination circuit 42 performs a determination operation in accordance with a signal output from the determination timing generation circuit 43. However, it may be configured such that the second determination circuit 42 performs a determination operation for every certain length of time without using the determination timing generation circuit 43.

What is claimed:

1. A PLL, comprising:
a plurality of VCOs whose oscillation frequency bands are different from each other;
a programmable frequency divider;
a charge pump; and
a VCO/current switching circuit configured to select one of the plurality of VCOs on a basis of frequency division data determining a frequency division ratio of the programmable frequency divider, and to switch a current value of the charge pump to a larger value than normal when switching the VCOs.

2. The PLL according to claim 1, wherein
the VCO/current switching circuit further comprises:
a first determination circuit configured to compare the frequency division data determining a frequency division ratio of the programmable frequency divider with a reference value, and to output a selection signal for selecting one VCO out of the plurality of VCOs;
a second determination circuit configured to compare a control voltage for controlling an oscillation frequency of a VCO with a first reference value and a second reference value, to select a currently selected VCO when the control voltage is determined to be equal to or higher than the first reference value and equal to or lower than the second reference value, to output a signal for selecting a VCO whose oscillation frequency band is next largest from the currently selected VCO when the control voltage is determined to be larger than the second reference value, and to output a signal for selecting a VCO whose oscillation frequency band is next smallest from the currently selected VCO when the control voltage is determined to be lower than the first reference value; and
a selector configured to select an output out of the first determination circuit and the second determination circuit, and to output the selected output as a VCO selection signal.

3. The PLL according to claim 2, wherein
when switching a reception channel, the selector firstly selects the first determination circuit, and from then on, selects the second determination circuit.

4. The PLL according to claim 2, wherein
when the frequency division data is modified, the selector firstly selects an output of the first determination circuit and outputs a switching signal for changing a current value of the charge pump to a larger value than normal, and from then on, when a signal for switching the VCOs is not output from the second determination circuit, the selector outputs a switching signal for changing a current value of the charge pump to a normal small value.
